(19) United States
(12) Patent Application Publication
(10) Pub. No.: US 2014/0346648 A1
(43) Pub. Date: Nov. 27, 2014

(54) LOW-K NITRIDE FILM AND METHOD OF MAKING

(71) Applicant: GLOBALFOUNDRIES INC., Grand Cayman (KY)

(72) Inventors: Huy CAO, Rexford, NY (US); Huang LIU, Mechanicville, NY (US); Vijayalakshmi SESHACHALAM, Clifton Park, NY (US)

(73) Assignee: GLOBALFOUNDRIES INC., Grand Cayman (KY)

(21) Appl. No.: 13/900,976

(22) Filed: May 23, 2013

(51) Int. Cl. H01L 21/02

(52) U.S. Cl. CPC H01L 21/02274; H01L 21/0228
USPC 257/632; 438/783

(57) ABSTRACT

A low-K nitride film and a method of making are disclosed. Embodiments include forming a nitride film on a substrate by plasma enhanced chemical vapor deposition (PECVD) and periodically fluctuating a production of radicals during the PECVD based, at least in part, on plural cycles of a radiofrequency (RF) induced plasma.

### TECHNICAL FIELD

The present disclosure relates to the formation of a low-K nitride film. The present disclosure particularly relates to low-K dielectrics in a back-end-of-line (FEOL/BEOL) process and is particularly applicable to 32 nanometers (nm), 28 nm, 20 nm, 14 nm and beyond semiconductor device technology nodes.

### BACKGROUND

Existing low-K dielectric materials (materials having a dielectric constant less than 3.9) are expensive both in terms of their fabrication and precursor raw materials. In a conventional BEOL process, the formation of a low-K and ultra-low-K (having a dielectric constant less than 2.5) dielectric film by a PECVD process requires the use of costly precursors (e.g., bicycloheptadiene (BCHD), methyldiethoxysilane (MDEOS), alpha terpinene (ATRP), octamethylcyclotetrasiloxane (OMCTS), and tetramethlysilane (4MS)). In addition, existing fabrication techniques are not easily integrated because their mode of operation is closely tied to vendor-specific tools and protocols.

A need therefore exists for a methodology enabling low-K nitride film formation that is transferrable to any PECVD tool and does not require the use of costly precursors, and the resulting device.

### SUMMARY

An aspect of the present disclosure is a method for producing a low-K nitride film.

Another aspect of the present disclosure is a low-K nitride film.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method comprising: forming a nitride film on a substrate by PECVD and periodically fluctuating a production of radicals during the PECVD based, at least in part, on plural cycles of a radiofrequency (RF) induced plasma.

Aspects of the present disclosure include tuning a duty cycle of the plural cycles between 10% and 90%. Other aspects include tuning a frequency of the RF induced plasma between 10 Hertz (Hz) and 1000 Hz. Further aspects include employing ammonia (NH₃), silane (SiH₄), and nitrogen (N₂) as process gases for the PECVD. Additional aspects include setting a pressure for the PECVD between 2 Torr (T) and 9 T. Other aspects include setting a temperature for the PECVD between 350° Celsius (C) and 475°. Further aspects include setting a first cycle of the plural cycles at 50 amperes (A) and a second and third consecutive cycle of the plural cycles at 100 A. Additional aspects include doping the nitride film with one or more elements, including carbon (C), carbon dioxide (CO₂), Argon (Ar), oxygen (O₂), helium (He), hydrogen (H₂) or some combination thereof.

Another aspect of the present disclosure is a device including a nitride film on a substrate formed by periodically fluctuating a production of radicals during a PECVD wherein the periodic fluctuation is based, at least in part, on plural cycles of a RF induced plasma.

Aspects include a duty cycle of the plural cycles being between 10% and 90%. Other aspects include a frequency of the RF induced plasma being between 10 Hz and 1000 Hz. Further aspects include one or more process gases used in the PECVD process including NH₃, SiH₄, and N₂. Additional aspects include a pressure setting for the PECVD process being between 2 T and 9 T. Other aspects include a temperature setting for the PECVD process being between 350° C. and 475° C. Further aspects include a first cycle of the plural cycles being at 50 A and a second and third consecutive cycle of the plural cycles being at 100 A. Additional aspects include one or more dopants in the nitride film, the dopants including C, CO₂, Ar, O₂, He, H₂, or some combination thereof.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1 graphically illustrates a plurality of cycles of a RF signal, in accordance with an exemplary embodiment of the present disclosure;

FIG. 2A schematically illustrates a morphology of a nitride film, in accordance with an exemplary embodiment of the present disclosure; and

FIG. 2B illustrates a chemical structure of a nitride film, in accordance with an exemplary embodiment of the present disclosure.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of costly precursor materials attendant upon forming low-K nitride films by a PECVD process. In accordance with embodiments of the present disclosure, a new PECVD-based process is utilized for the formation of low-K nitride films.

Methodology in accordance with embodiments of the present disclosure includes periodically fluctuating a production of radicals based on a plurality of cycles of a RF induced plasma. Additional aspects include precisely controlling the cycles of the RF signal in a rhythmic or on/off phase to control the porosity and doping of the nitride film.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

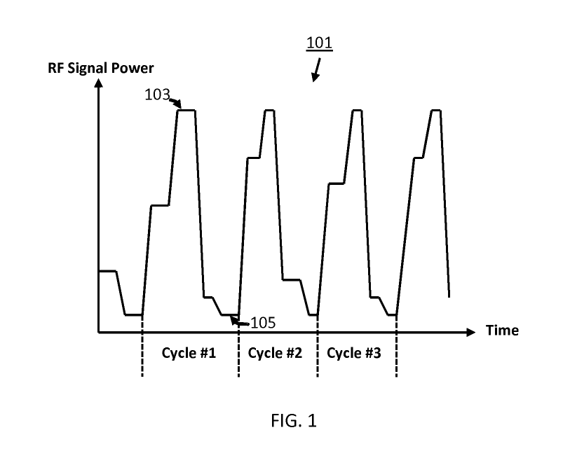

FIG. 1 graphically illustrates a plurality of cycles of a RF signal 101, in accordance with an exemplary embodiment of the present disclosure. The frequency and the duty cycle of the RF signal 101 may be adjusted to modify the properties of a nitride film. For example, the etch rate (ER), film density, refractive index (RI), and non-uniformity (NU) may be adjusted by varying the frequency and/or duty cycle of the RF signal 101. The frequency may vary between 10 Hz and 1000 Hz. The duty cycle may vary from 10% to 90%. Various process gases may be used for the PECVD process, including NH₃, SiH₄, and N₂. The selection of a process gas may depend on various factors, including an intended application of the film (e.g., surface pre-treatment), etch resistance, or other desired film property.

The plasma is turned on and off corresponding to the peaks 103 and the troughs 105 of the RF signal 101. Within a cycle (e.g., cycle #1), the ratio of the duration of the peak 103 relative to the duration of the trough 105 (i.e., duty cycle) may be controlled to increase or decrease the production of plasma radicals. To create an equal amount of nitride deposition on the upper and lower surfaces of a gap surface, the duty cycle may be adjusted to specifically operate the plasma in a surface reaction-limited regime and avoid operation in a transport-limited regime. For example, a low deposition rate may be achieved by only creating radicals 10% of the time while the other 90% of the time the system is reacting on the surface. The ratio of process gas flow may be adjusted to ensure enough Siₓ:N_{y} that the amount of reaction taking place on the upper and lower surfaces of the gap is roughly equal.

In addition to varying the frequency and duty cycle of the RF signal 101, the pressure may also be varied to adjust the mean free path of the sputter molecules. The pressure may vary from 2 T to 9 T. The temperature may vary from 300° C. to 475° C. At higher pressures the mean free path may be very short. As a result, the upper surfaces of the gap may be bombarded more than the lower surfaces, thus causing greater sputter-like reactivity at the higher surfaces. As a result, the sidewall thickness of the gap surface may gradually increase from the bottom to the top of the trench.

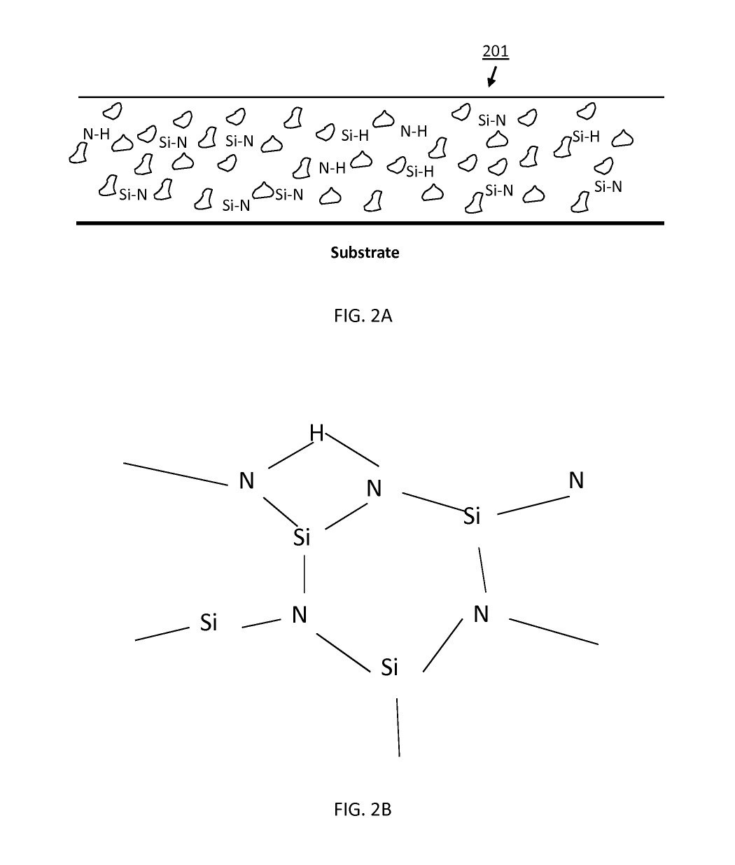

FIG. 2A schematically illustrates a morphology of a nitride film 201, in accordance with an exemplary embodiment of the present disclosure. As shown, a nitride film 201 may include both nitrides of hydrogen (e.g., N—H) and silicon (e.g., Si—N). By varying the duty cycle of the PECVD process, the porosity of the nitride film 201 may be increased or decreased to enable the film to be doped with various elements, including C, CO₂, Ar, O₂, He, and H₂. FIG. 2B illustrates a chemical structure 211 of the nitride film 201, in accordance with an exemplary embodiment of the present disclosure. As shown, the chemical structure 211 may include hydrogen and nitride groups.

The embodiments of the present disclosure can achieve several technical effects, include controlled porosity of the nitride film to allow doping with a wide range of materials. The present disclosure enjoys industrial applicability in any of various BEOL processes used to produce devices for various industrial applications as, for example, microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in any of various highly integrated semiconductor devices.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
Forming a nitride film on a substrate by plasma enhanced chemical vapor deposition (PECVD); and
periodically fluctuating a production of radicals during the PECVD based, at least in part, on plural cycles of a radiofrequency (RF) induced plasma.

2. The method according to claim 1, further comprising:
Tuning a duty cycle of the plural cycles between 10% and 90%.

3. The method according to claim 1, further comprising:
Tuning a frequency of the RF induced plasma between 10 Hertz (Hz) and 1000 Hz.

4. The method according to claim 1, comprising employing ammonia (NH₃), silane (SiH₄), and nitrogen (N₂) as process gases for the PECVD.

5. The method according to claim 1, comprising setting a pressure for the PECVD between 2 Torr (T) and 9 T.

6. The method according to claim 1, comprising setting a temperature for the PECVD between 350° Celsius (C) and 475° C.

7. The method according to claim 1, comprising setting a first cycle of the plural cycles at 50 amperes (A) and a second and third consecutive cycle of the plural cycles at 100 A.

8. The method according to claim 1, further comprising:
doping the nitride film with one or more elements, including carbon (C), carbon dioxide (CO₂) cobalt (Co), Argon (Ar), oxygen (O₂), helium (He), hydrogen (H₂) or some combination thereof.

9. A device comprising:
a nitride film on a substrate formed by periodically fluctuating a production of radicals during a plasma enhanced chemical vapor deposition (PECVD),
wherein the periodic fluctuation is based, at least in part, on plural cycles of a radiofrequency (RF) induced plasma.

10. The device according to claim 9, wherein a duty cycle of the plural cycles is between 10% and 90%.

11. The device according to claim 9, wherein a frequency of the RF induced plasma is between 10 Hertz (Hz) and 1000 Hz.

12. The device according to claim 9, wherein one or more process gases used in the PECVD process include ammonia (NH₃), silane (SiH₄), and nitrogen (N₂).

13. The device according to claim 9, wherein a pressure setting for the PECVD process is between 2 Torr (T) and 9 T.

14. The device according to claim 9, wherein a temperature setting for the PECVD process is between 350° Celsius (C) and 475° C.

15. The device according to claim 9, wherein a first cycle of the plural cycles is at 50 amperes (A) and a second and third consecutive cycle of the plural cycles is at 100 A.

16. The device according to claim 9, further comprising:
one or more dopants in the nitride film, the dopants including carbon (C), carbon dioxide (CO₂), Argon (Ar), oxygen (O₂), helium (He), hydrogen (H₂), or some combination thereof.

17. A method comprising:
forming a nitride film on a wafer by plasma enhanced chemical vapor deposition (PECVD); and
periodically fluctuating an on/off phase during the PECVD,
wherein the periodic fluctuation is based, at least in part, on plural cycles of a radiofrequency (RF) induced plasma, a duty cycle of the plural cycles being between 10% and 90%, and a frequency of the RF induced plasma being between 10 Hertz (Hz) and 1000 Hz.

18. The method according to claim 17, comprising employing ammonia (NH₃), silane (SiH₄), and nitrogen (N₂) as process gases for the PECVD.

19. The method according to claim 17, comprising setting a pressure for the PECVD between 2 Torr (T) and 9 T.

20. The method according to claim 17, comprising setting a temperature for the PECVD between 350° Celsius (C) and 475° C.
